(19) United States
(12) Patent Application Publication
(10) Pub. No.: US 2019/0249671 A1
(43) Pub. Date: Aug. 15, 2019

(54) PUMP DEVICE

(71) Applicant: NIDEC SANKYO CORPORATION, NAGANO (JP)

(72) Inventor: Noboru OTSUKI, NAGANO (JP)

(73) Assignee: NIDEC SANKYO CORPORATION, NAGANO (JP)

(21) Appl. No.: 16/254,621

(22) Filed: Jan. 23, 2019

(30) Foreign Application Priority Data
Feb. 14, 2018 (JP) 2018-023705

(51) Int. Cl. F04D 13/06; H05K 5/00; H05K 1/11

(52) U.S. Cl. CPC F04D 13/06; H05K 5/0026; H05K 2201/1009; H05K 2201/10287; H05K 2201/09027; H05K 1/117

(57) ABSTRACT

In a pump device, in a flat plate-shaped circuit board that is disposed so that the axial direction of a central rotating shaft and the thickness direction coincide with each other, a notch that a cut-out from an end face of the circuit board toward an inside of the circuit board is formed. In the vicinity of the notch on a surface of the circuit board, a solder land where a plurality of core wires that are exposed on the distal end side of a lead wire are fixed by soldering is formed. In the pump device, the distal end portion of a cover portion including the distal end of the cover portion of the lead wire drawn out from the circuit board is disposed in the notch.

### CROSS REFERENCE TO RELATED APPLICATION

The present application claims priority under 35 U.S.C. § 119 to Japanese Application No. 2018-023705 filed Feb. 14, 2018, and the entire content of which is incorporated herein by reference.

### BACKGROUND

### Technical Field

The present disclosure relates to a pump device that includes a motor and an impeller rotated by the power of the motor.

Description of the Related Documents

Conventionally, a pump device that includes a motor having a rotor and a stator and an impeller rotated by the power of the motor is known (for example, refer to Patent Document 1: Japanese Unexamined Patent Application Publication No. 2017-216759). The pump device described in Patent Document 1 includes a circuit board for controlling the motor and a fixed shaft for rotatably supporting the rotor. The impeller is fixed to the rotor on one end side in the axial direction of the fixed shaft. The circuit board is a rigid board formed in a flat plate shape and disposed so that the thickness direction of the circuit board and the axial direction of the fixed shaft coincide. Further, the circuit board is fixed to the stator on the other end side in the axial direction of the fixed shaft. On the circuit board, a connector is mounted. To the connector, a predetermined cable is connected.

In the pump device described in Patent Document 1, the connector is mounted on the circuit board disposed so that the axial direction of the fixed shaft and the thickness direction coincide. Therefore, in this pump device, the amount of protrusion of the connector from a surface of the circuit board on the other end side in the axial direction of the fixed shaft may be large, which may result in an increased thickness of the pump device in the axial direction of the fixed shaft.

### SUMMARY

Therefore, the present disclosure provides a pump device that includes a motor, an impeller configured to be rotated by the power of the motor, and a circuit board configured to control the motor, so that the pump device can be thinner in the axial direction of the central rotating shaft that is the rotation center of the impeller.

In order to solve the above problems, a pump device according to the present disclosure includes: a motor including a rotor and a stator, an impeller fixed to the rotor and configured to be rotated by a power of the motor, a circuit board configured to control the motor, and at least one lead wire drawn out from the circuit board. The at least one lead wire includes: a plurality of core wires formed of an electrically conductive material, and a cover portion formed of an insulating material and covering peripheries of the plurality of core wires. Distal end portions of the plurality of core wires are an exposed portion protruding from a distal end of the cover portion to expose. The impeller is fixed on a side of a first direction of the rotor, and the circuit board is a rigid board having a flat plate shape and is disposed on a side of a second direction of the stator, where the first direction is defined as a direction toward one side in an axial direction of a central rotating shaft serving as a rotation center of the rotor and the impeller, and the second direction is defined as an opposite direction to the first direction. A thickness direction of the circuit board coincides with the axial direction of the central rotating shaft. At least one notch that is a cut-out from an end face of the circuit board toward an inside of the circuit board is formed in the circuit board. A solder land where the exposed portion is fixed by soldering is formed in a vicinity of the at least one notch on a surface of the circuit board on the side of the second direction, and a distal end portion of the cover portion including the distal end of the cover portion is disposed in the at least one notch.

With the pump device according to the present disclosure, in the flat plate-shaped circuit board that is disposed so that the axial direction of the central rotating shaft and the thickness direction coincide with each other, and the notch that is a cut-out from an end face of the circuit board toward an inside of the circuit board is formed. Further, according to the present disclosure, the solder land where the plurality of core wires (the exposed portion) exposed on the distal end side of the lead wire is fixed by soldering is formed in the vicinity of the notch on the surface of the circuit board on the side of the second direction, and the distal end portion of the cover portion including the distal end of the cover portion of the lead wire drawn out from the circuit board is disposed in the notch. Accordingly, in the present disclosure, it is possible to reduce the amount of protrusion of the cover portion of the lead wire from the surface, on the side of the second direction, of the circuit board disposed on the side of the second direction of the stator. Therefore, in the present disclosure, it is possible to make the pump device thinner in the axial direction of the central rotating shaft.

In the present disclosure, in the pump device, for example, the at least one lead wire includes a plurality of lead wires, and the at least one notch includes a plurality of notches which are formed in the circuit board at predetermined intervals.

In the present disclosure, it is preferable that the at least one notch has a rectangular shape, when being viewed from the axial direction of the central rotating shaft, and side faces of the at least one notch are composed of two perpendicular faces that are perpendicular to an end face of the circuit board, and a connecting face that is perpendicular to the two perpendicular faces and connects ends of the two perpendicular faces. With this configuration, it is possible to regulate the movement of the distal end portion of the cover portion disposed in the notch by the notch. Therefore, it is possible to stabilize the state of the exposed portion when the exposed portion is soldered to the solder land, and as a result, it makes it easy to solder the exposed portion to the solder land.

In the present disclosure, it is preferable that the distal end of the cover portion is in contact with the connecting face. With this configuration, the distal end portion of the cover portion disposed in the notch is positioned in the longitudinal direction of the lead wire. Therefore, it is possible to stabilize the state of the exposed portion better when the exposed portion is soldered to the solder land, and as a result, it makes it easy to solder the exposed portion to the solder land.

In the present disclosure, it is preferable that the pump device further includes: a motor case in which the circuit board is housed, a wall portion being formed in the motor case and surrounding the circuit board, and a second notch being formed in the wall portion and being a cut-out from an end face of the wall portion on the side of the second direction toward the side of the first direction. The second notch is adjacent to the at least one notch, and a part of the cover portion is disposed in the second notch. That is, in the present disclosure, it is preferable that the lead wire is drawn out to an outer peripheral side of the wall portion by utilizing the second notch that is a cut-out from the end face of the wall portion on the side of the second direction toward the side of the first direction.

With this configuration, it is easier to draw out the lead wire to the outer peripheral side of the wall portion, as compared with the case where a through hole for drawing out the lead wire to the outer peripheral side of the wall portion is formed in the wall portion. That is, in the case where the through hole for drawing out the lead wire to the outer peripheral side of the wall portion is formed in the wall portion, an operation of passing the lead wire through the through hole is required. By contrast, with the above-configuration, the lead wire has only to be fitted into the second notch from the side of the second direction. Therefore, it makes it easy to draw out the lead wire to the outer peripheral side of the wall portion.

In the present disclosure, it is preferable that the at least one lead wire is covered with an adhesive on an inner peripheral side of the wall portion. With this configuration, it is possible to fix the cover portion to the circuit board by the adhesive. Therefore, it is possible to prevent an excessive load from being applied to the exposed portion soldered to the solder land. In addition, it is possible to stabilize the state of the distal end portion of the cover portion disposed in the notch by the adhesive.

It is noted that in the present disclosure, since the notch that is a cut-out from the end face of the circuit board toward the inside of the circuit board is formed in the circuit board, it is possible to lengthen the distance from the end face of the circuit board to the solder land. That is, it is possible to lengthen the length of the cover portion that is disposed on an inner circumferential side of the wall portion and is covered with the adhesive. As a result, it is possible to increase the fixing strength of the cover portion disposed on the inner circumferential side of the wall portion onto the circuit board. Therefore, it is possible to effectively prevent the excessive load from being applied to the exposed portion soldered to the solder land, and also the adhesive makes it possible to stabilize the state of the distal end portion of the cover portion disposed in the notch better.

In the present disclosure, it is preferable that an upper portion of the cover portion in the at least one notch is filled with an adhesive.

In the present disclosure, it is preferable that an outer peripheral surface of the cover portion is in contact with a bottom face of the at least one notch.

As described above, the present disclosure makes it possible to make the pump device, which includes the motor, the impeller configured to be rotated by the power of the motor, and the circuit board configured to control the motor, thinner in the axial direction of the central rotating shaft that is the rotation center of the impeller.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional view of a pump device according to an embodiment of the present disclosure.

FIG. 2 is a perspective view of the pump device with a cover being removed from the state shown in FIG. 1.

FIG. 3A is a plan view of part E in FIG. 2, and FIG. 3B is a cross-sectional view taken along line F-F of FIG. 3A.

### DETAILED DESCRIPTION

Next, an embodiment of the present disclosure will be described with reference to the drawings.

(Overall Configuration of Pump Device)

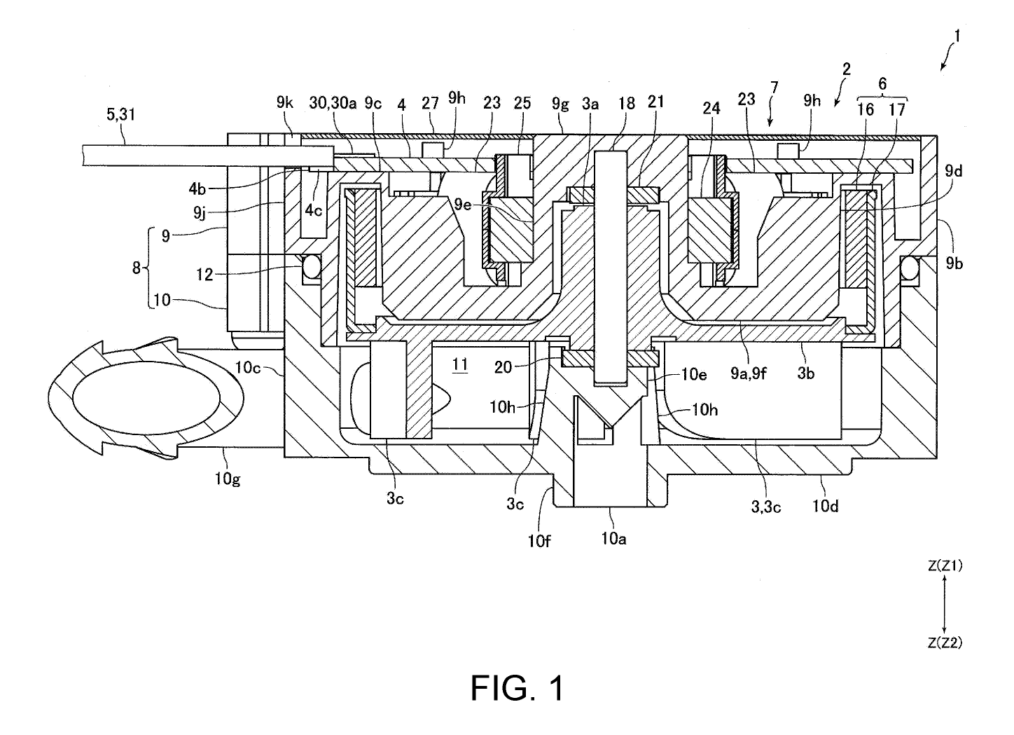

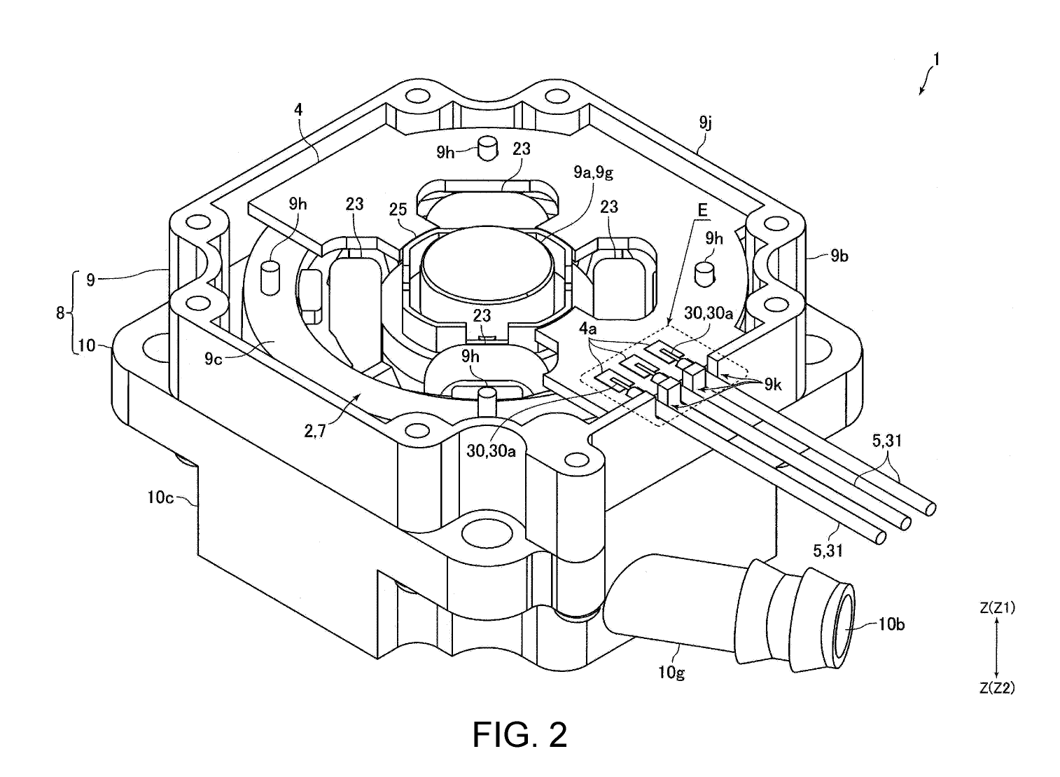

FIG. 1 is a cross-sectional view of a pump device 1 according to an embodiment of the present disclosure. FIG. 2 is a perspective view of the pump device 1 with a cover 27 being removed from the state shown in FIG. 1. In the following description, the Z direction in FIG. 1 is referred to as the “vertical direction”. In addition, the Z1 direction side of FIG. 1, which is one side in the vertical direction, is defined as the “upper” side, and the Z2 direction side, which is the opposite side, is defined as the “lower” side.

The pump device 1 of the present embodiment is a centrifugal pump of a type called a canned pump (canned motor pump). The pump device 1 includes a motor 2, an impeller 3 configured to be rotated by the power of the motor 2, a circuit board 4 configured to control the motor 2, and a lead wire 5 drawn from the circuit board 4. The pump device 1 of the present embodiment has three lead wires 5. The motor 2 is a DC brushless motor. The motor 2 includes a rotor 6 and a stator 7. The impeller 3, the rotor 6, and the stator 7 are housed in a pump case 8. The pump case 8 includes a motor case 9 constituting a part of the motor 2 and a case body 10 fixed on the lower end side of the motor case 9.

In the case body 10, a suction port 10a for liquid such as water and a discharge port 10b for the liquid are formed. Inside the pump case 8, a pump chamber 11 through which liquid sucked from the suction port 10a passes toward the discharge port 10b is formed. The pump chamber 11 is defined by the motor case 9 and the case body 10. At a joint portion between the motor case 9 and the case body 10, an annular seal member 12 for ensuring sealing of the pump chamber 11 is disposed. The seal member 12 is an O-ring. The motor case 9 and the case body 10 are fixed to each other by a plurality of screws.

The rotor 6 includes a driving magnet 16 formed in a circular-cylindrical shape and a circular-cylindrical magnet holding member 17 to which the driving magnet 16 is fixed. The magnet holding member 17 formed in a circular-cylindrical shape is disposed so that the axial direction of the magnet holding member 17 and the vertical direction coincide with each other. The driving magnet 16 is fixed to the inner peripheral surface of the magnet holding member 17. On the inner peripheral surface of the driving magnet 16, N poles and

S poles are alternately magnetized in the circumferential direction. The magnet holding member 17 is formed of a soft magnetic material. On the lower end side of the magnet holding member 17, the impeller 3 is fixed. In other words, the impeller 3 is fixed on the lower end side of the rotor 6.

The impeller 3 and the rotor 6 are arranged inside the pump chamber 11. Further, the impeller 3 and the rotor 6 are rotatably supported by a fixed shaft 18. The impeller 3 and the rotor 6 rotate around the fixed shaft 18 serving as a rotation center. The fixed shaft 18 of the present embodiment is a central rotating shaft which is the rotation center of the impeller 3 and the rotor 6. The fixed shaft 18 is disposed so that the axial direction of the fixed shaft 18 and the vertical direction coincide with each other. That is, the vertical direction (Z direction) is the axial direction of the fixed shaft 18. Further, the downward direction (Z2 direction) in the present embodiment is a first direction that is a direction toward one side of the axial direction of the fixed shaft 18, and the upward direction (Z1 direction) is a second direction that is the opposite direction to the first direction.

The impeller 3 is made of resin. The impeller 3 includes a bearing portion 3a through which the fixed shaft 18 is inserted, a disk-shaped blade forming portion 3b fixed to the lower end of the magnet holding member 17 to close the lower end of the magnet holding member 17, and a plurality of blades 3c protruding downward from the lower surface of the blade forming portion 3b. The bearing portion 3a is formed in a circular-cylindrical shape, and the fixed shaft 18 is inserted on the inner peripheral side of the bearing portion 3a. Further, the bearing portion 3a is connected to the center of the blade forming portion 3b. To the lower end of the magnet holding member 17, an outer peripheral side portion of the blade forming portion 3b is fixed.

A lower end portion of the fixed shaft 18 is held by the case body 10, and an upper end portion of the fixed shaft 18 is held by the motor case 9. Between the case body 10 and the bearing portion 3a, a thrust bearing 20 is disposed; between the motor case 9 and the bearing portion 3a, a thrust bearing 21 is disposed. The thrust bearings 20 and 21 are slide bearings that are each formed in a flat plate shape. Either between the thrust bearing 20 and the bearing portion 3a or between the thrust bearing 21 and the bearing portion 3a, or both, a gap (thrust play) is formed.

The stator 7 is disposed on the inner peripheral side of the driving magnet 16. That is, the motor 2 of the present embodiment is an outer rotor type motor in which the driving magnet 16 constituting a part of the rotor 6 is disposed on the outer peripheral side of the stator 7. Further, the stator 7 is disposed on the outer peripheral side of the fixed shaft 18 and the bearing portion 3a. The stator 7 is also disposed outside the pump chamber 11. The stator 7 includes a plurality of driving coils 23 and a stator core 24. The driving coil 23 is wound around the stator core 24 via an insulator 25 formed of an insulating material such as resin. Further, the driving coil 23 is electrically connected to the circuit board 4.

The circuit board 4 is a rigid board such as a glass epoxy substrate and is formed in a flat plate shape. The circuit board 4 is disposed so that the thickness direction of the circuit board 4 and the vertical direction coincide with each other. In other words, the thickness direction of the circuit board 4 coincides with the axial direction of the fixed shaft 18. Further, the circuit board 4 is disposed on the upper end side of the stator 7. The circuit board 4 and the stator core 24 are housed in the motor case 9.

The motor case 9 is made of resin. The motor case 9 is also provided between the stator 7 and a set of the impeller 3 and the rotor 6, and has a partition wall 9a separating the set of the impeller 3 and the rotor 6 from the stator 7. The partition wall 9a defines a part of the pump chamber 11 and performs the function of preventing the inflow of the liquid in the pump chamber 11 into the place where the stator 7 and the circuit board 4 are arranged.

The partition wall 9a has a cylindrical outer partition wall portion 9d disposed on the outer peripheral side of the stator 7 and the inner peripheral side of the driving magnet 16, a cylindrical inner partition wall portion 9e disposed on the inner peripheral side of the stator 7, an annular partition wall portion 9f connecting a lower end of the outer partition wall portion 9d and a lower end of the inner partition wall portion 9e, and a bottom portion 9g closing an upper end of the inner partition wall portion 9e. The bottom portion 9g is a shaft holding portion for holding the upper end portion of the fixed shaft 18. The bottom portion 9g holds the upper end portion of the fixed shaft 18 and holds the thrust bearing 21.

Further, the motor case 9 includes a cylindrical outer peripheral cylindrical portion 9b disposed on the outer peripheral side of the partition wall 9a, and a connecting portion 9c connecting the partition wall 9a and the outer peripheral cylindrical portion 9b. The case body 10 is fixed on the lower end side of the outer peripheral cylindrical portion 9b. The connecting portion 9c is formed in an annular shape and is also formed in a flat plate shape perpendicular to the vertical direction. The connecting portion 9c extends outward in the radial direction of the rotor 6 from an upper end of the outer partition wall portion 9d and connects an upper end portion of the outer peripheral cylindrical portion 9b and the upper end of the outer partition wall portion 9d. The upper surface of the connecting portion 9c is disposed below the top face of the outer peripheral cylindrical portion 9b. On the upper surface of the connecting portion 9c, a plurality of protrusions 9h for positioning and fixing the circuit board 4 are formed.

As described above, the circuit board 4 and the stator core 24 are housed in the motor case 9. The stator core 24 is housed between the outer partition wall portion 9d and the inner partition wall portion 9e in the radial direction of the rotor 6 and also housed above the annular partition wall portion 9f. The circuit board 4 is housed in the motor case 9 so as to come into contact with the upper surface of the connecting portion 9c. A part of the outer cylindrical portion 9b is a wall portion 9j surrounding the circuit board 4. The wall portion 9j is formed in a substantially square-cylindrical shape. The top face of the wall portion 9j is the top face of the outer peripheral cylindrical portion 9b. The top face of the wall portion 9j is the top face of the motor case 9.

An opening formed at the upper end of the wall portion 9j is closed by the cover 27.

The cover 27 is formed in a thin flat plate shape and is disposed so that the thickness direction of the cover 27 coincides with the vertical direction. The cover 27 is disposed on the upper side of the circuit board 4. The end face (outer peripheral surface) of the cover 27 is in contact with the inner side surface of the wall portion 9j. At the center of the cover 27, a through hole in which the upper end portion of the bottom portion 9g is disposed is formed. The outer peripheral surface of the bottom portion 9g is in contact with the edge of the through hole. The upper surface of the cover 27, the top face of the wall portion 9j, and the top face of the bottom portion 9g are arranged at substantially the same position in the vertical direction.

A space defined by the motor case 9 and the cover 27 (that is, a space defined by the partition wall 9a, the outer peripheral cylindrical portion 9b, the connecting portion 9c, and the cover 27) is filled with a resin sealing member made of potting resin. In other words, the circuit board 4 and the stator 7 are covered with a potting resin.

The case body 10 is made of resin. The case body 10 is formed in a bottomed cylindrical shape that has a cylindrical portion 10c formed in a cylindrical shape and a bottom portion 10d closing one end of the cylindrical portion 10c. The axial direction of the cylindrical portion 10c formed in a cylindrical shape coincides with the vertical direction. The bottom portion 10d closes the lower end of the cylindrical portion 10c. The inner circumferential side of the cylindrical portion 10c and the upper side of the bottom portion 10d constitute the pump chamber 11. The case body 10 is provided with a shaft holding portion 10e that holds the lower end portion of the fixed shaft 18, a circular-cylindrical suction port forming portion 10f having a distal end at which the suction port 10a is formed, and a circular-cylindrical discharge port forming portion 10g having a distal end at which the discharge port 10b is formed.

The shaft holding portion 10e is connected to the center portion of the bottom portion 10d via a connecting portion 10h. The shaft holding portion 10e holds the lower end portion of the fixed shaft 18 and also holds the thrust bearing 20. The suction port forming portion 10f protrudes downward from the center of the bottom portion 10d. The discharge port forming portion 10g protrudes from the outer peripheral surface of the cylindrical portion 10c toward the outer peripheral side.

(Configuration of Lead Wire and Configuration of Connecting Portion of Circuit Board and Lead Wire)

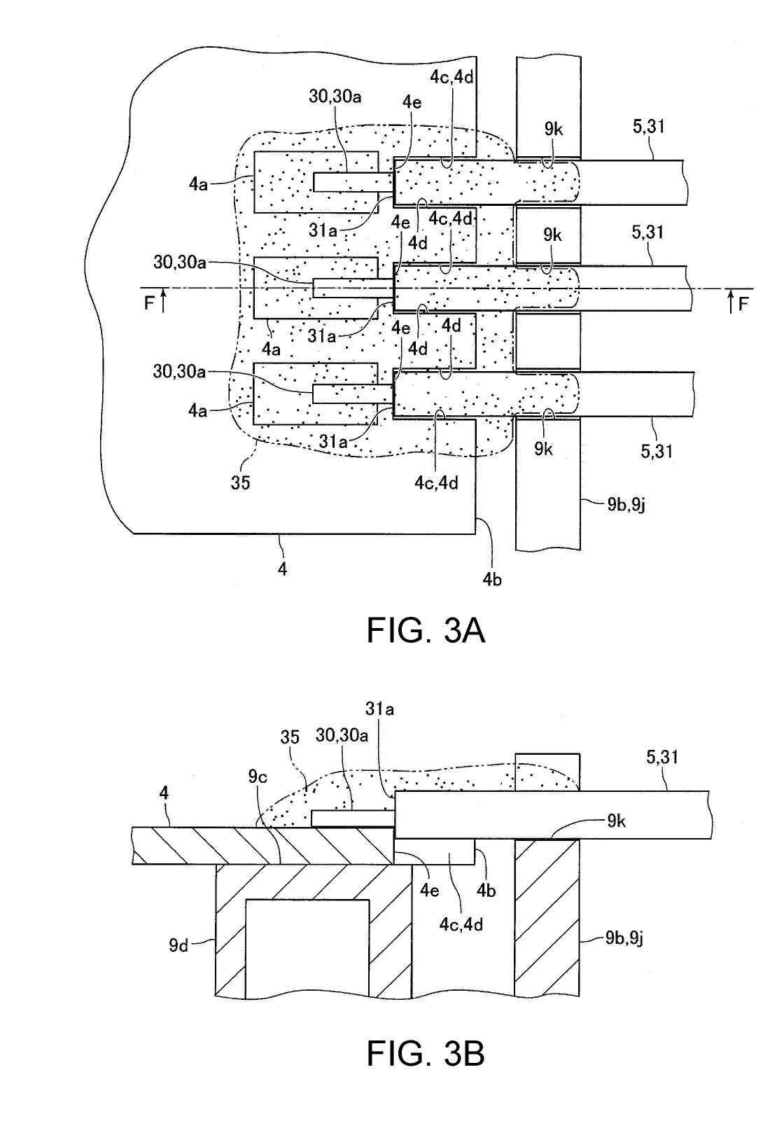

FIG. 3A is a plan view of part E in FIG. 2, and FIG. 3B is a cross-sectional view taken along line F-F of FIG. 3A.

The lead wire 5 is composed of a plurality of core wires 30 formed of a conductive material and a cover portion 31 formed of an insulating material and covering the periphery of the plurality of core wires 30. The distal end portions of the plurality of core wires 30 are an exposed portion 30a that protrudes from a distal end 31a of the cover portion 31 to expose. On the upper surface of the circuit board 4, a solder land 4a to which the exposed portion 30a is fixed by soldering is formed. Since the pump device 1 of the present embodiment includes three lead wires 5 as described above, three solder lands 4a are formed on the upper surface of the circuit board 4. The exposed portion 30a is in contact with the upper surface of the solder land 4a.

Further, on the circuit board 4, a notch 4c that is a cut-out from one end face 4b of the circuit board 4 toward the inside of the circuit board 4 is formed. The end face 4b is a flat face parallel to the vertical direction. Between the inner peripheral surface of the wall portion 9j that faces the end face 4b and the end surface 4b, a gap is formed. Further, the inner peripheral surface of the wall portion 9j that faces the end face 4b is parallel to the end surface 4b. The notch 4c is formed in the entire region in the thickness direction of the circuit board 4 (the entire region in the vertical direction). In the present embodiment, three notches 4c are formed in the circuit board 4. The three notches 4c are formed at predetermined intervals along the end face 4b.

The solder land 4a is formed in the vicinity of the notch 4c. The notch 4c is disposed between the solder land 4a and the end face 4b. The direction in which the three solder lands 4a are arranged coincides with the direction in which the three notches 4c are arranged. That is, the direction in which the three solder lands 4a are arranged coincides with the direction along which the end faces 4b are aligned. Further, the pitch of the three solder lands 4a coincides with the pitch of the three notches 4c.

The shape of the notch 4c when viewed from the vertical direction is a rectangular shape. The side face of the notch 4c is composed of two perpendicular faces 4d perpendicular to the end face 4b and a connecting face 4e connecting the ends of the two perpendicular faces 4d. The perpendicular faces 4d and the connecting face 4e are flat faces parallel to the vertical direction. The connecting face 4e is perpendicular to the two perpendicular faces 4d. That is, the connecting face 4e is parallel to the end face 4b.

In the notch 4c, the distal end portion of the cover portion 31 including the distal end 31a of the cover portion 31 is disposed. Specifically, the lower portion of the distal end portion of the cover portion 31 is disposed in the notch portion 4c. Further, each of the distal end portions of the cover portions 31 of the three lead wires 5 is disposed in the corresponding one of the three notches 4c. The distal end 31a of the cover portion 31 is in contact with the connecting face 4e. There is a slight gap between the outer peripheral surface of the cover portion 31 and each perpendicular surface 4d.

In the wall portion 9j, a notch 9k serving as a second notch that is a cut-out from the top face of the wall portion 9j toward the lower side is formed. Specifically, the notch 9k is formed in a portion of the wall portion 9j that faces the end face 4b of the circuit board 4. Further, the notch 9k is formed in the vicinity of the notch 4c in the wall portion 9j, and the notch 9k is adjacent to the notch 4c. The notch 9k is formed across the region in the thickness direction of the wall portion 9j.

In the present embodiment, three notches 9k are formed at predetermined intervals. The direction in which the three notches 9k are arranged coincides with the direction in which the three notches 4c are arranged. Further, the pitch of the three notches 9k coincides with the pitch of the three notches 4c, and the three notches 9k are adjacent to the respective three notches 4c. The solder land 4a, the notch 4c, and the notch 9k are arranged on a straight line.

In the notch 9k, a part of the cover portion 31 is disposed, and the lead wire 5 is drawn out to the outer peripheral side of the wall portion 9j through the notch 9k. The outer peripheral surface of the cover portion 31 is in contact with the bottom face of the notch 9k. There is a slight gap between the outer peripheral surface of the cover portion 31 and each side face of the notch 9k.

On the inner peripheral side of the wall portion 9j, the lead wire 5 is covered with an adhesive 35. That is, the cover portion 31 disposed on the inner peripheral side of the wall portion 9j and the exposed portion 30a are covered with the adhesive 35. Further, the solder land 4a is also covered with the adhesive 35. The cover portion 31 disposed on the inner peripheral side of the wall portion 9j is fixed to the end portion of the circuit board 4 by the adhesive 35. Further, in the present embodiment, the portion of the cover portion 31 disposed in the notch 9k is also covered with the adhesive 35. That is, an upper portion of the cover portion 31 in the notch 9k is filled with the adhesive 35. A portion of the cover portion 31 disposed in the notch 9k is fixed to the wall portion 9j by the adhesive 35. In FIG. 1 and FIG. 2, the adhesive 35 is not shown.

In the present embodiment, after the lead wires 5 are soldered to the circuit board 4, the circuit board 4 is placed on the upper surface of the connecting portion 9c of the motor case 9 with the stator 7 being attached thereto so that a part of the cover portion 31 is disposed in the notch 9k. Thereafter, the adhesive 35 is applied and cured, and then the circuit board 4 and the stator 7 are covered with a potting resin. As a result, the adhesive 35 disposed on the inner peripheral side of the wall portion 9j is covered with a potting resin filling a space defined by the motor case 9 and the cover 27. It is noted that the viscosity of the adhesive 35 is higher than the viscosity of the potting resin.

(Main Effect of Present Embodiment)

As described above, in the present embodiment, in the flat plate-shaped circuit board 4, which is disposed so that the vertical direction and the thickness direction coincide with each other, the notch 4c, which a cut-out from the end face 4b of the circuit board 4 toward the inside of the circuit board 4, is formed. Further, in the present embodiment, the solder land 4a is formed in the upper surface of the circuit board 4 in the vicinity of the notch 4c, and the distal end of the cover portion 31 of the lead wire 5 is disposed in the notch 4c. Therefore, in the present embodiment, it is possible to reduce the amount of protrusion of the cover portion 31 from the upper surface of the circuit board 4. Accordingly, in the present embodiment, it is possible to prevent interference between the upper end of the cover portion 31 and the cover 27 even if the height of the wall portion 9j surrounding the circuit board 4 is reduced. As a result, in the present embodiment, it is possible to make the pump device 1 thinner in the vertical direction.

In the present embodiment, it is preferable that the notch 4c has a rectangular shape when viewed from the vertical direction, and the side faces of the notch 4c are composed of two perpendicular faces 4d that are perpendicular to the end face 4b of the circuit board 4, and the connecting face 4e that is perpendicular to the two perpendicular faces 4d and connects the ends of the two perpendicular faces 4d. Accordingly, in the present embodiment, it is possible to regulate the movement of the distal end portion of the cover portion 31 disposed in the notch 4c by the notch 4c. Therefore, in the embodiment, it is possible to stabilize the state of the exposed portion 30a when the exposed portion 30a is soldered to the solder land 4a, and as a result, it makes it easy to solder the exposed portion 30a to the solder land 4a.

In particular, in the present embodiment, since the distal end 31a of the cover portion 31 is in contact with the connecting face 4e of the notch 4c, the distal end portion of the cover portion 31 disposed in the notch 4c is positioned in the longitudinal direction of the lead wire 5. Therefore, in the embodiment, it is possible to stabilize the state of the exposed portion 30a better when the exposed portion 30a is soldered to the solder land 4a, and as a result, it makes it easier to solder the exposed portion 30a to the solder land 4a.

In the present embodiment, the lead wire 5 is drawn out to the outer peripheral side of the wall portion 9j through the notch portion 9k that is a cut-out from the top face of the wall portion 9j toward the lower side. Accordingly, in the present embodiment, it is easier to draw out the lead wire 5 to the outer peripheral side of the wall portion 9j, as compared with the case where a through hole for drawing out the lead wire 5 to the outer peripheral side of the wall portion 9j is formed in the wall portion 9j. That is, in the case where the through hole for drawing out the lead wire 5 to the outer peripheral side of the wall portion 9j is formed in the wall portion 9j, an operation of passing the lead wire 5 through the through hole is required. By contrast, in the present embodiment, the lead wire 5 has only to be fitted into the notch 9k from the upper side. Therefore, in the present embodiment, it is easy to draw out the lead wire 5 to the outer peripheral side of the wall portion 9j.

In the present embodiment, the cover portion 31 disposed in the inner peripheral side of the wall portion 9j is covered with the adhesive 35 and is fixed to the end portion of the circuit board 4 by the adhesive 35. Accordingly, in the present embodiment, it is possible to prevent an excessive load from being applied to the exposed portion 30a soldered to the solder land 4a. Further, in the present embodiment, it is possible to stabilize the state of the distal end portion of the cover portion 31 disposed in the notch 4c by the adhesive 35. Further, in the present embodiment, since each of the distal end portions of the cover portions 31 of the three lead wires 5 is disposed in the corresponding one of the three notches 4c, it is possible to secure the fixing strength of the cover portion 31 to the end portion of the circuit board 4 even if the notch 4c is formed in the circuit board 4.

Further, in the present embodiment, since the notch 4c is formed in the circuit board 4, the distance from the end face 4b of the circuit board 4 to the solder land 4a can be increased. That is, it is possible to lengthen the length of the cover portion 31 that is disposed on the inner peripheral side of the wall portion 9j and is covered with the adhesive 35. As a result, it is possible to increase the fixing strength of the cover portion 31 disposed on the inner peripheral side of the wall portion 9j onto the circuit board 4. Therefore, it is possible to effectively prevent the excessive load from being applied to the exposed portion 30a soldered to the solder land 4a, and also the adhesive 35 makes it possible to stabilize the state of the distal end portion of the cover portion 31 disposed in the notch 4c better.

In the present embodiment, the upper portion of the cover portion 31 in the notch 9k is filled with the adhesive 35. Accordingly, in the present embodiment, when a potting resin is poured so as to cover the circuit board 4 and the stator 7, it is possible to prevent the potting resin from flowing out from the notch 9k to the outer peripheral side of the wall portion 9j.

### Other Embodiments

The above-described embodiment is an example of a preferred embodiment of the present disclosure, but the present disclosure is not limited thereto, and various modifications can be made without changing the gist of the present disclosure.

In the above-described embodiment, the upper portion of the cover portion 31 in the notch 9k does not have to be filled with the adhesive 35. Further, in the above-described embodiment, the cover portion 31 and the exposed portion 30a that are disposed on the inner peripheral side of the wall portion 9j do not have to be covered with the adhesive 35. In this case, the cover portion 31 and the exposed portion 30a that are disposed on the inner peripheral side of the wall portion 9j are covered with a potting resin. Further, in the above-described embodiment, in place of the notch 9k, a through hole for drawing out the lead wire 5 to the outer peripheral side of the wall portion 9j may be formed in the wall portion 9j.

In the above-described embodiment, a gap may be formed between the distal end 31a of the cover portion 31 and the connecting face 4e. Further, in the above-described embodiment, the outer peripheral surface of the cover portion 31 may be in contact with the two perpendicular faces 4d. Further, in the above-described embodiment, the shape of the notch 4c when viewed from the vertical direction may be a shape other than a rectangular shape.

In the above-described embodiment, the number of lead wires 5 included in the pump device 1 may be one, two, or four or more. In this case, the solder land 4a, the notch 4c, and the notch 9k are formed depending on the number of lead wires 5. Further, in the above-described embodiment, the motor 2 may include a rotating shaft to which the impeller 3 is fixed in place of the fixed shaft 18. In this case, the rotating shaft is the central rotating shaft serving as the rotation center of the impeller 3 and the rotor 6. Furthermore, in the above-described embodiment, the motor 2 may be an inner rotor type motor.

What is claimed is:

1. A pump device, comprising:
a motor, including a rotor and a stator;
an impeller, fixed to the rotor and configured to be rotated by a power of the motor;
a circuit board, configured to control the motor; and
at least one lead wire, drawn out from the circuit board,
wherein
the at least one lead wire includes:
a plurality of core wires, formed of an electrically conductive material, and
a cover portion, formed of an insulating material and covering peripheries of the plurality of core wires,
distal end portions of the plurality of core wires are an exposed portion protruding from a distal end of the cover portion to expose,
the impeller is fixed on a side of a first direction of the rotor, and the circuit board is a rigid board having a flat plate shape and is disposed on a side of a second direction of the stator, where the first direction is defined as a direction toward one side in an axial direction of a central rotating shaft serving as a rotation center of the rotor and the impeller, and the second direction is defined as an opposite direction to the first direction,
a thickness direction of the circuit board coincides with the axial direction of the central rotating shaft,
at least one notch that is a cut-out from an end face of the circuit board toward an inside of the circuit board is formed in the circuit board,
a solder land where the exposed portion is fixed by soldering is formed in a vicinity of the at least one notch on a surface of the circuit board on the side of the second direction, and
a distal end portion of the cover portion including the distal end of the cover portion is disposed in the at least one notch.

2. The pump device according to claim 1, wherein
the at least one lead wire comprises a plurality of lead wires, and
the at least one notch comprises a plurality of notches which are formed in the circuit board at predetermined intervals.

3. The pump device according to claim 1, wherein
the at least one notch has a rectangular shape, when being viewed from the axial direction of the central rotating shaft; and
side faces of the at least one notch are composed of two perpendicular faces that are perpendicular to an end face of the circuit board, and a connecting face that is perpendicular to the two perpendicular faces and connects ends of the two perpendicular faces.

4. The pump device according to claim 3, wherein
the distal end of the cover portion is in contact with the connecting face.

5. The pump device according to claim 1, further comprising:
a motor case, in which the circuit board is housed;
a wall portion, being formed in the motor case and surrounding the circuit board; and
a second notch, being formed in the wall portion and being a cut-out from an end face of the wall portion on the side of the second direction toward the side of the first direction;
wherein the second notch is adjacent to the at least one notch; and
a part of the cover portion is disposed in the second notch.

6. The pump device according to claim 5, wherein
the at least one lead wire is covered with an adhesive on an inner peripheral side of the wall portion.

7. The pump device according to claim 6, wherein
an upper portion of the cover portion in the at least one notch is filled with an adhesive.

8. The pump device according to claim 5, wherein
an outer peripheral surface of the cover portion is in contact with a bottom face of the at least one notch.
